(19) United States
(12) Patent Application Publication
(10) Pub. No.: US 2014/0272401 A1
(43) Pub. Date: Sep. 18, 2014

(54) ADHESIVE FILM HAVING GOOD MACHINABILITY FOR PROTECTING THE SURFACE OF A SEMICONDUCTOR WAFER

(71) Applicant: LG Hausys, Ltd., Seoul (KR)

(72) Inventors: Jang Soon Kim, Seongnam-si (KR); Hyun Ju Cho, Gunpo-si (KR); Ju Yong Seo, Daejeon (KR)

(73) Assignee: LG Hausys, Ltd., Yeongdeungpo-gu, Seoul (KR)

(21) Appl. No.: 14/350,445

(22) PCT Filed: Oct. 22, 2012
(86) PCT No.: PCT/KR2012/008666

§ 371 Date: Apr. 8, 2014

(30) Foreign Application Priority Data
Nov. 2, 2011 (KR) 10-2011-0113294

(51) Int. Cl. H01L 21/683

(52) U.S. Cl. CPC H01L 21/6836
USPC 428/337; 428/343; 427/558

(57) ABSTRACT

The present invention relates to an adhesive film for protecting a wafer including an adhesive layer formed on one surface of a substrate film. The present invention relates to an adhesive film for protecting the surface of a semiconductor wafer, wherein the surface film has a tensile strength of 2-10 kg/mm² and an elongation until breakage of 50-200%, and the gel content of the adhesive layer is greater than or equal to 80%. The adhesive film for protecting the wafer maintains cutting ability and machinability, while preventing the generation of bending and wafer breaking phenomena due to the decrease of the wafer thickness. In addition, the adhesive film may not melt at high temperatures, and the yield while grinding the wafer may be increased.

### TECHNICAL FIELD

The present invention relates to an adhesive film for protecting a semiconductor wafer, which includes a base film and an adhesive layer formed on one surface of the base film.

### Background Art

An adhesive film for protecting a semiconductor wafer must be cut well without resistance under any conditions when cut in a wafer shape, and such a property is referred to as machinability or cuttability. With this regard, in practice, there are problems in that cuttability is not secured after bonding an adhesive film to a wafer, and that the wafer suffers from higher warpage with decreasing thickness.

Although Korean Patent Publication No. 2003-0061300A discloses stiffness depending on temperature, such problems in the art have not been yet solved.

Generally, although an adhesive used as a wafer protective film does not provide great influence on cuttability due to thin thickness thereof, a polymer film used as a base film provides extremely great influence on cuttability. Therefore, there is an urgently need for a method capable of improving wafer chip yield by securing cuttability of the base film.

### DISCLOSURE

### Technical Problem

It is one aspect of the present invention to provide an adhesive film for protecting a surface of a semiconductor wafer, which is used in wafer grinding and exhibits excellent cuttability and machinability, and a method for preparing the same.

It is another aspect of the present invention to provide an adhesive film for protecting a surface of a semiconductor wafer, which prevents warpage and breakage of the wafer despite thin thickness of the wafer, and a method for preparing the same.

### Technical Solution

In accordance with one aspect of the present invention, an adhesive film for protecting a surface of a semiconductor wafer includes a base film and an adhesive layer formed on one surface of the base film, wherein the base film has a tensile strength from 2 kg/mm² to 10 kg/mm² and an elongation at break from 50% to 200%, and the adhesive layer has a gel content of 80% or more.

In accordance with another aspect of the present invention, a method for preparing an adhesive film for protecting a surface of a semiconductor wafer includes: forming a base film; controlling tensile strength and elongation at break of the base film; forming an adhesive layer on one surface of the base film; and performing UV curing of the base film on which the adhesive layer is formed.

### Advantageous Effects

The adhesive film for protecting a wafer, which includes the base film and the adhesive layer formed on one surface of the base film, secures cuttability and machinability, and does not melt at high temperature and thus can improve yield upon wafer grinding.

In addition, since the method for preparing an adhesive film for protecting a surface of a wafer includes controlling tensile strength and elongation at break of the base film, the method can reduce resistance to cutting while securing cuttability allowing a clean surface to be maintained. Further, when the wafer becomes thin, the method according to the present invention can minimize warpage of the wafer, thereby preventing breakage of the wafer.

### Best Mode

The above and other aspects, features, and advantages of the present invention will become apparent from the detailed description of the following embodiments in conjunction with the accompanying drawings. It should be understood that the present invention is not limited to the following embodiments and may be embodied in different ways, and that the embodiments are provided for complete disclosure and thorough understanding of the present invention by those skilled in the art. The scope of the present invention is defined only by the claims. Like components will be denoted by like reference numerals throughout the specification.

Hereinafter, embodiments of the present invention will be described in detail.

Adhesive Film for Protecting Surface of Wafer

The present invention provides an adhesive film for protecting a semiconductor wafer which includes a base film and an adhesive film formed on one surface of the base film.

To exhibit excellent cuttability, the base film must have tensile strength and elongation at break within an optimized range. Here, the base film may have a tensile strength from 2 kg/mm² to 10 kg/mm² and an elongation at break from 50% to 200%. When the base film has a tensile strength from 2 kg/mm² to 10 kg/mm², the base film exhibits low resistance to cutting, and can secure extremely clean cuttability. If the base film has a tensile strength of less than 2 kg/mm², the base film is considered soft and can exhibit high resistance to cutting. In addition, if the base film has a tensile strength of greater than 10 kg/mm², the base film is deteriorated in capabilities of absorbing shock when peeled off, whereby a wafer can suffer from curling with decreasing thickness thereof during wafer grinding.

Elongation at break is also an important factor. The base film may have an elongation at break from 50% to 200%. If the base film has an elongation at break of less than 50%, there is a high possibility that the wafer suffers from curling with decreasing thickness thereof during wafer grinding as in the case of high tensile strength. In addition, if the base film has an elongation at break of greater than 200%, since it is implied that the base film has a long arrangement of polymers in a stretching direction, the base film can exhibit high resistance to cutting.

The base film may include at least one selected from the group consisting of polyvinyl chloride (PVC), polyurethane, polyolefin, ethylene-vinyl acetate (EVA) copolymer, and ethylene-alkyl acrylate copolymer films. Since the thickness of the base film has influence on strength and prevention of wafer breakage during processing of a rear surface of the wafer, the thickness of the base film may be appropriately selected depending on surface profile of the wafer, presence or absence of bump electrodes, and the like.

The base film may have a thickness from about 50 μm to about 300 μm, specifically from about 100 μm to about 200 μm. If the base film is too thin, the base film is deteriorated in strength and exhibits insufficient adhesion to bumps on the surface of the wafer due to insufficient step coverage for the bumps, and the wafer can suffer from dimples on the rear surface thereof corresponding to the bumps.

If the base film is too thick, it is difficult to prepare the adhesive film, and the thick base film affects productivity of the adhesive film and thus can increase manufacturing costs.

According to the invention, the adhesive layer formed on one surface of the base film may have a gel content of 80% or more. Specifically, the adhesive layer may have a gel content of 80% to 99%, considering that machinability and cuttability of the film can be secured due to increase in hardness of a polymer. If the adhesive layer has a gel content of less than 80%, the film is soft and thus is deteriorated in cuttability, thereby causing a high possibility of burring, and unreacted components can protrude from the surface of the film, thereby causing blocking when the film is stored in a film roll state for a long time. In addition, if the adhesive layer has a gel content of greater than 99%, although the film exhibits excellent machinability due to hardness thereof, there is a possibility of low yield since the film does not absorb shock during wafer grinding and has a high possibility of curling.

Here, the gel content is measured after immersing a resin composition included in the adhesive layer in a polar solvent for 48 hours, followed by drying at 110° C. for 2 hours, as represented by Equation 1:

X(Gel content)=[1−(Xi−Xs)/Xi]×100(%),

wherein Xi is an initial weight of the resin composition; Xs is a weight of organic materials which remain on a 300 mesh screen after the resin composition is dissolved in a solvent and filtered through the 300 mesh screen, followed by drying at 110° C. for 2 hours; and X means the gel content described herein.

Although the resin composition may have a different elapsed time for dissolving and separating a sol fraction depending on polarity of the solvent, since only gel fraction remains through sufficient separation of the sol fraction after about 24 hours to 48 hours, the polar solvent according to the invention may be any solvent without limitation so long as the solvent has even slight polarity. Examples of the polar solvent may include chloroform, ethyl acetate, acetone, methanol, ethanol, isopropanol, butanol, dimethyl formamide, and the like.

According to the invention, the resin composition forming the adhesive layer of the adhesive film for protecting a semiconductor wafer may sufficiently function as an adhesive at a temperature to which the semiconductor wafer is heated, for example, even at about 150° C. However, even when the resin composition is heated to 150° C. or more, it is desirable that the resin composition not cause peeling failure and residues due to increase in adhesion thereof.

The resin composition may include a silicone or acrylic resin composition. Here, the resin composition preferably includes an acrylic resin composition. As the acrylic resin composition, a UV curable acrylic resin composition is most universally used. In particular, the UV curable acrylic resin composition is generally applied when the wafer has a thin thickness of 100 μm or less after stretching.

The resin composition may be hydrophobic. If the resin composition is water-soluble, there is a possibility of deterioration in process accuracy due to dislocation caused by swelling of a cured product of the resin composition during wafer grinding. However, even though the resin composition is water-soluble, there is no limit in using the resin composition so long as the cured product thereof is not swollen by water or is not partially dissolved in water.

The adhesive layer may have a thickness from 3 μm to 300 μm. After the adhesive film for protecting a semiconductor wafer is peeled off of a circuit-formed surface (hereinafter, referred to as a surface) of the wafer, it is desirable the adhesive layer not contaminate the surface of the semiconductor wafer due to adhesive residues and the like. In particular, the adhesive layer may be cross-linked to high density by a reactive functional group-containing cross-linking agent, peroxide, radiation and the like such that, even though the adhesive layer is subjected to heating after bonding the adhesive film to the circuit-formed surface of the semiconductor wafer, the adhesive layer does not exhibit too high adhesion and increase contamination of the of the semiconductor wafer.

According to the invention, the adhesive film exhibits higher peel strength before UV irradiation than peel strength after UV irradiation. More specifically, the adhesive film may have a peel strength before UV irradiation from 400 g/in to 1200 g/in, and a peel strength after UV irradiation from 20 g/in to 200 g/in.

If the adhesive film has a peel strength before UV irradiation of less than 400 g/in, there is a high possibility of water permeation due to low initial peel strength of the film. If the adhesive film has a peel strength before UV irradiation of higher than 1200 g/in, there is a high possibility that residues remain on the wafer after UV irradiation due to high initial adhesion and extremely high adhesion to the wafer, or burrs can be generated due to the soft adhesive layer, and that warpage can occur due to the thin thickness of the wafer after grinding.

In addition, if the adhesive film has a peel strength after UV irradiation of less than 20 g/in, the adhesive film can be naturally detached from the wafer during handling of the UV-irradiated wafer, thereby causing contamination of the surface of the wafer. If the adhesive film has a peel strength after UV irradiation of higher than 200 g/in, the adhesive film is not easily detached, thereby causing breakage of the wafer.

Method for Preparing Adhesive Film for Protecting Surface of Wafer

The present invention provides a method for preparing an adhesive film for protecting a surface of a semiconductor wafer, which includes: forming a base film; controlling tensile strength and elongation at break of the base film; forming an adhesive layer on one surface of the base film; and performing UV curing of the base film on which the adhesive layer is formed.

Formation of the base film may be performed by a process such as extrusion, UV curing, casting, calendering, thermal curing, and the like.

An acrylic film may be formed through UV curing, ethylene-vinyl acetate and polyolefin films may be formed through extrusion, and a polyurethane film may be formed through thermal curing. Further, a polyvinyl chloride film may be formed through casting or calendaring.

In controlling tensile strength and elongation at break of the base film, the base film is controlled to a tensile strength from 2 kg/mm² to 10 kg/mm² and to an elongation at break from 50% to 200%. After the base film is formed by the method as described above, the base film is subjected to electromagnetic wave irradiation or plasma treatment to control tensile strength and elongation at break. In addition, in controlling tensile strength and elongation at break of the base film, the base film may be subjected to electromagnetic wave irradiation or plasma treatment.

The electromagnetic waves may include gamma rays, X-rays, ultraviolet rays, electron beams, and the like. Preferably, the electromagnetic wave is an ultraviolet ray or an electron beam. In particular, the ultraviolet ray is preferably used due to easy handling and high energy easily obtained therefrom, and any light source generating the ultraviolet ray may be used. For example, the light source may include low pressure, medium pressure, high pressure and ultra high pressure mercury lamps, carbon arc lamps, metal halide lamps, xenon lamps, and the like. In addition, the light source may include ArF excimer lasers, KrF excimer lasers, excimer lamps, xenon lamps, and the like.

Further, the light source may also include ArF excimer lasers, KrF excimer lasers, excimer lamps, synchrotron radiation, and the like. Although irradiation conditions vary with lamps, irradiation is performed at an intensity of 1 mJ/cm² or more, preferably from 200 mJ/cm² to 10,000 mJ/cm², more preferably from 500 mJ/cm² to 5,000 mJ/cm².

In addition, the electron beam may include electron beams having energy emitted from various electron beam accelerators such as Cockcroft Walton, Van de Graff, resonance transformer, insulated core transformer, linear, dynamitron, high frequency accelerators, and the like.

An electron beam irradiation apparatus may include aerial electron beam, scanning electron beam irradiation apparatuses, and the like. As for irradiation conditions, acceleration voltage may be appropriately selected based on film thickness or desired treatment depth. The acceleration voltage may be 50 kV or more. Irradiation intensity may be appropriately selected based on desired properties of the film. The irradiation intensity may be from 50 kGy to 1000 kGy. If the irradiation intensity is not within this range, since there is a high possibility that the film is too soft or hard, it is difficult to control the film to desired cuttability and curl. In addition, when severely high irradiation intensity is applied to the film, deterioration in performance of the film may be caused.

As for plasma treatment, atmospheric plasma treatment may be specifically performed. In addition, a noble gas such as helium, argon and the like, or a discharge gas such as nitrogen, air and the like may be used. Further, a reactive gas including at least one of oxygen, hydrogen, nitrogen, carbon monoxide, carbon dioxide, nitrogen monoxide, nitrogen dioxide, water vapor, methane, methane tetrafluoride and the like may be used, as needed.

In addition, the operation of controlling tensile strength and elongation at break of the base film may vary according to the operation of forming the base film. For example, when the base film is prepared through extrusion, the base film is subjected to electron beam curing due to deteriorated machinability caused by arrangement of polymer chains. On the other hand, since the base film such as an acrylic film and a polyvinyl chloride film prepared through casting has relatively uniform arrangement of polymer chains and thus exhibits excellent machinability, the base film prepared through casting can secure cuttability and machinability without electron beam curing thereof.

When the base film includes at least two layers, a film stacked on the base film may not be subjected to electron beam irradiation. Specifically, the film stacked on the base film may include a resin film formed from polyethylene, ethylene-vinyl acetate copolymers, ethylene-alkyl acrylate copolymers (wherein the alkyl group is a C₁ to C₄ alkyl group), ethylene-α-olefin copolymers, propylene-α-olefin copolymers, polyolefin such as polypropylene and the like, polyester such as polyethylene terephthalate, polyethylene naphthalate and the like, polyimide, polyetheretherketone, polyethersulfone, polyethylene, polypropylene, urethane, liquid crystals, and mixtures thereof.

The method for preparing an adhesive film according to the invention may include forming an adhesive layer on one surface of the base film. Forming an adhesive layer on one surface of the base film may be performed using a process known in the art, for example, roll coating, reverse roll coating, gravure roll coating, bar coating, comma coating, die coating, and the like. Generally, the formed adhesive layer may be subjected to drying at a temperature from 80° C. to 200° C. for 10 seconds to 10 minutes, without being limited thereto. Preferably, the adhesive layer is subjected to drying at a temperature from 80° C. to 170° C. for 15 seconds to 5 minutes. To promote sufficient cross-linking reaction between the cross-linking agent and the adhesive layer, the adhesive film may be heated at 40° C. to 80° C. for 5 hours to 300 hours after completion of drying of the adhesive layer.

The adhesive layer may include the silicone or acrylic resin composition, as described above. More specifically, a hydroxyl group-containing resin composition may be prepared through copolymerization by solution polymerization of 2-ethylhexyl acrylate (2-EHA), 2-ethylhexyl methacrylate (2-EHMA), 2-hydroxyethyl acrylate (2-HEA) and an acrylic acid monomer in a solvent.

The method according to the invention may include performing UV curing of the base film on which the adhesive layer is formed.

That is, a semiconductor wafer-protective film is prepared by transfer-coating the adhesive layer onto the base film, and then laminated on the wafer before wafer grinding, followed by grinding the wafer. Next, peel strength of the wafer is reduced by UV irradiation, followed by artificial detachment of the protective film, thereby completing wafer grinding.

More specifically, when the resin composition forming the adhesive layer includes acrylic acid as a functional group, primary thermal curing is performed using the resin composition including an aziridine or epoxy group as a thermal curing agent, and when the resin composition includes a hydroxyl group as the functional group, primary thermal curing is performed using the resin composition including an isocyanate group as the thermal curing agent. Here, curing reaction by UV irradiation of branched double bonds, which is not involved in reaction in the resin composition subjected to primary thermal curing, is induced by introducing a photoinitiator into the resin composition, thereby obtaining lower peel strength than that of the film subjected to primary thermal curing.

That is, peel strength before UV curing is measured after the adhesive film is subjected to primary thermal curing, and peel strength after UV curing is measured after the film subjected to thermal curing is attached to the wafer, followed by UV irradiation. Here, the adhesive film may have a peel strength before UV irradiation from 400 g/in to 1200 g/in, and a peel strength after UV irradiation from 20 g/in to 150 g/in.

Hereinafter, the present invention will be described in more detail with reference to some examples. It should be understood that these examples are provided for illustration only and are not to be in any way construed as limiting the present invention.

### EXPERIMENTAL EXAMPLE 1

### Evaluation of Machinability and Cuttability of Base Film

### Examples and Comparative Examples

Different types of base films were used as listed in Tables 1 and 2, and each of the base films was controlled to different tensile strength and elongation at break according to a process of forming the base film, thereby measuring machinability and cuttability of the base film.

TABLE 1

| | Example 1 | Example 2 | Example 3 | Example 4 | Example 5 | Example 6 |
|---|---|---|---|---|---|---|
| Base film | EVA | Acrylic | Polyolefin | PVC | PVC | Polyurethane |
| | | film | film | | | film |
| Process of | Extrusion | UV curing | Extrusion | Casting | Calendering | Thermal |
| forming base film | | | | | | curing |
| Electron beam | 500 | — | 50 | — | 100 | — |
| (kGy) | | | | | | |
| Tensile strength | 6 | 3 | 8 | 9 | 4 | 5.0 |
| (kg/mm²) | | | | | | |
| Elongation at | 50 | 100 | 120 | 80 | 110 | 180 |
| break (%) | | | | | | |

TABLE 2

| | Comparative | Comparative | Comparative | Comparative | Comparative | Comparative |
|---|---|---|---|---|---|---|
| | Example 1 | Example 2 | Example 3 | Example 4 | Example 5 | Example 6 |
| Base film | EVA | Acrylic | Polyolefin | PVC | PVC | Polyurethane |
| | | film | film | | | film |
| Process of | Extrusion | UV | Extrusion | Casting | Calendering | Thermal |
| forming base film | | curing | | | | curing |
| Electron beam | 200 | 500 | 30 | 30 | — | 600 |
| (kGy) | | | | | | |
| Tensile strength | 1.5 | 13 | 6 | 16 | 1.0 | 28 |
| (kg/mm²) | | | | | | |
| Elongation at | | | | | | |
| break (%) | 400 | 30 | 250 | 10 | 300 | 5 |

<Property Evaluation>

Each specimen of the base films according to Tables 1 and 2 having a thickness of 100 μm was prepared to a size of 5 cm×1 cm (length×width), followed by securing upper and lower portions of the specimen to tensile tester using jigs, thereby performing tensile testing under a load of a load cell of 30 kg. Here, elongation at break was measured using an obtained curve in which horizontal axis and vertical axis components represent distance and force, respectively, and a maximum force when the film was broken was measured as tensile strength.

In relation to evaluation of final cuttability, when a cut portion was created in the middle of a specimen prepared to a size of 10 cm×10 cm (length×width) using an extremely sharp knife, and then opened in left and right directions, if the film was torn well without resistance, the film was evaluated as exhibiting good cuttability. However, when the film was torn and it was not easy to open the cut portion of the film, generation of burrs was observed.

For evaluation of curling, first, an adhesive was coated to a thickness of 20 μm onto the base film, followed by bonding the base film to a 50 μm thick aluminum sheet having a size of 10 cm×10 cm. Next, the aluminum sheet was left at 100° C. for about 10 minutes, followed by leaving the sheet at room temperature, in order to observe warpage of the aluminum sheet. When the aluminum sheet had a warped edge separated from the floor due to curling of the sheet, if the height of the warped edge was greater than about 2 mm, it was evaluated that the aluminum sheet suffered from curling, and if the height of the warped edge was less than about 2 mm, it was evaluated that the aluminum sheet did not suffer from curling.

<Results>

As shown in Tables 3 and 4, it could be seen that, when the film had severely low or high tensile strength and elongation at break which were not in the range of tensile strength from 2 kg/mm² to 10 kg/mm² and in the range of elongation at break from 50% to 200%, respectively, the film failed to secure cuttability and machinability due to burring and curling. In addition, it could be seen that, although the results varied according to materials of the base films, the adhesive film showed the same trend of deterioration in cuttability and machinability when the film had tensile strength and elongation at break, which are not within the above ranges.

Further, it could be confirmed that, since the operation of controlling tensile strength and elongation at break varied according to the operation of forming the base film, the adhesive film maintained cuttability and machinability even without electron beam irradiation so long as the base film was adjusted in terms of mechanical properties so as to have tensile strength and elongation at break within the range according to the invention.

TABLE 3

| | Example | Example | Example | Example | Example | Example |
|---|---|---|---|---|---|---|
| | 1 | 2 | 3 | 4 | 5 | 6 |
| Cuttability | Good | Good | Good | Good | Good | Good |
| Curling | None | None | None | None | None | None |

TABLE 4

| | Comparative | Comparative | Comparative | Comparative | Comparative | Comparative |
|---|---|---|---|---|---|---|
| | Example 1 | Example 2 | Example 3 | Example 4 | Example 5 | Example 6 |
| Cuttability | Poor | Good | Poor | Good | Poor | Good |
| Curling | None | Severe | None | Severe | None | Severe |

### EXPERIMENTAL EXAMPLE 2

### Evaluation of Gel Content of Adhesive Layer and Peel Strength of Adhesive Film

### Examples and Comparative Examples

Base films were prepared using different types of base films as listed in Tables 5 and 6, and an adhesive layer was formed on one surface of each of the prepared base films. The adhesive layer included an acrylic resin composition, and the resin composition included 60 parts by weight of ethylhexyl acrylate, 20 parts by weight of methyl acrylate, and 20 parts by weight of hydroxyethyl acrylate, based on 100 parts by weight in total of the resin composition. Next, the resin composition was mixed with ethyl acetate as a solvent, followed by introducing 0.01 parts by weight of 2,2-azobisisobutyronitrile (AIBN, Japan) as a thermal initiator into the resin composition, based on 100 parts by weight of the resin composition. Next, the resin composition was heated to 60° C., followed by polymerizing the resin composition into a polymeric resin having a molecular weight of 500,000 over 8 hours.

Next, 90 parts by weight of methacryloyloxyethyl isocyanate (MOI) was introduced into the resin composition based on 100 parts by weight of hydroxyethyl acrylate, followed by denaturation at 25° C. for 24 hours, thereby reacting a hydroxyl group of the resin composition with isocyanate (NCO) of MOI. Next, Irgacure 651 as a photo-initiator and 1,6-hexamethylene diisocyanate (HDI) as a curing agent were introduced into and mixed with the resin composition, followed by coating the resin composition onto a 38 μm thick PET release film and drying the resin composition, thereby preparing a 20 μm thick adhesive layer. Next, the prepared adhesive layer was transferred to each of the base films of Examples and Comparative Examples according to Tables 5 and 6, followed by aging at 40° C. for 3 days, thereby preparing a semi-cured adhesive film for protecting a surface of a semiconductor wafer.

TABLE 5

| | Example 7 | Example 6 | Example 9 |
|---|---|---|---|
| Base film | EVA | Acrylic film | Acrylic film |
| Process of forming | Extrusion | UV curing | UV curing |
| base film | | | |
| Thermal curing | 1.0 parts by | 1.5 parts by | 2.0 parts by |
| agent HDI | weight | weight | weight |
| Irgacure 651 | 5.0 parts by | 5.0 parts by | 5.0 parts by |
| | weight | weight | weight |

TABLE 6

| | Comparative | Comparative | Comparative |
|---|---|---|---|
| | Example 7 | Example 6 | Example 9 |
| Base film | EVA | Acrylic film | Acrylic film |
| Process of forming | Extrusion | UV curing | UV curing |
| base film | | | |
| Thermal curing | 0.3 parts by | 0.1 parts by | 4.5 parts by |
| agent HDI | weight | weight | weight |
| Irgacure 651 | 5.0 parts by | 5.0 parts by | 5.0 parts by |
| | weight | weight | weight |

<Property Evaluation>

Each of the prepared adhesive films according to Tables 5 and 6 was cut to a width of 1 inch by a length of 10 cm, and then attached to a surface of a polyimide substrate by moving a 2 kg roller back and forth on the adhesive film 5 times. After 30 minutes, using a universal testing machine (UTM), peel strength before UV irradiation was measured on the adhesive film at a peeling speed of 300 mm/min Next, the adhesive film attached to the surface of the polyimide substrate was subjected to UV irradiation at an intensity of 1500 mJ/cm², thereby measuring peel strength after UV irradiation in the same manner as in the above method. In addition, each of the adhesive films before UV irradiation was immersed in water in a tray, and maintained for 24 hours while being immersed in water, followed by observing whether the adhesive film suffered from water permeation. The specimen was removed from the water and left at room temperature for 24 hours, followed by complete drying. Next, the adhesive film for protection was subjected to UV irradiation again, and then peeled off, followed by observing whether residues remained on the polyimide substrate, thereby recording observation results.

In addition, the adhesive layer formed on one surface of the base film was immersed in ethyl acetate for 1 day, and then filtered through a 300 mesh screen, followed by drying at 110° C. for 2 hours. Then, gel content was measured based on the decreased weight of the adhesive layer.

<Results>

As shown in Tables 7 and 8, when the adhesive film had a peel strength before UV irradiation of higher than 1200 g/in, the residues remained on the substrate after UV irradiation even though the adhesive film did not suffer from water permeation, and when the adhesive film had a peel strength before UV irradiation of less than 400 g/in, the adhesive film suffered from water permeation even though the residues did not remain on the substrate after UV irradiation. In addition, it could be seen that it was most appropriate when the adhesive film had a peel strength after UV irradiation from 20 g/in to 200 g/in. Further, it could be confirmed that the adhesive layer formed on one surface of the base film securing cuttability and machinability had a gel content from 50% to 90%.

Consequently, it could be seen that, when the base film was included in the type of base film according to the invention, and had tensile strength and elongation at break within the range according to the invention, the resin composition forming the adhesive layer formed on one surface of the base film maintained constant gel content, and the adhesive film, which was formed of the base film and the adhesive layer, had a certain range of peel strength before or after UV irradiation, thereby facilitating wafer grinding during wafer processing.

TABLE 7

| | Example 7 | Example 8 | Example 9 |
|---|---|---|---|
| Peel strength before UV irradiation | 850 g/in | 740 g/in | 550 g/in |
| Peel strength after UV irradiation | 110 g/in | 85 g/in | 70 g/in |
| Water permeation | None | None | None |
| Residue | None | None | None |
| Gel content of adhesive layer (%) | 95 | 85 | 80 |

TABLE 8

| | Comparative | Comparative | Comparative |
|---|---|---|---|
| | Example 7 | Example 8 | Example 9 |
| Peel strength before UV | 1800 g/in | 2200 g/in | 230 g/in |
| irradiation | | | |
| Peel strength after UV | 150 g/in | 180 g/in | 63 g/in |
| irradiation | | | |
| Water permeation | None | None | None |
| Residue | Generation | Generation | Generation |
| Gel content of adhesive | 40 | 68 | 38 |
| layer (%) | | | |

1. An adhesive film for protecting a surface of a semiconductor wafer, comprising:
a base film; and
an adhesive layer formed on one surface of the base film,
wherein the base film has a tensile strength from 2 kg/mm² to 10 kg/mm² and an elongation at break from 50% to 200%, and the adhesive layer has a gel content of 80% or more.

2. The adhesive film according to claim 1, wherein the adhesive film has higher peel strength before UV irradiation than peel strength after UV irradiation.

3. The adhesive film according to claim 1, wherein the adhesive film has a peel strength before UV irradiation from 400 g/in to 1200 g/in, and a peel strength after UV irradiation from 20 g/in to 200 g/in.

4. The acrylic resin film according to claim 1, wherein the base film comprises at least one selected from the group consisting of polyvinyl chloride, polyurethane, polyolefin, ethylene-vinyl acetate copolymer, and ethylene-alkyl acrylate copolymer films.

5. The acrylic resin film according to claim 1, wherein the base film has a thickness from 50 μm to 300 μm.

6. A method for preparing an adhesive film for protecting a surface of a semiconductor wafer, comprising:
forming a base film;
controlling tensile strength and elongation at break of the base film;
forming an adhesive layer on one surface of the base film; and
performing UV curing of the base film on which the adhesive layer is formed.

7. The method according to claim 6, wherein the base film is controlled to a tensile strength from 2 kg/mm² to 10 kg/mm² and to an elongation at break from 50% to 200%.

8. The method according to claim 6, wherein the forming an adhesive layer on one surface of the base film is performed by any one process selected from among roll coating, reverse roll coating, gravure roll coating, bar coating, comma coating, and die coating.

9. The method according to claim 6, wherein the adhesive film has a peel strength before UV irradiation from 400 g/in to 1200 g/in, and a peel strength after UV irradiation from 20 g/in to 200 g/in.
